(19) United States
(12) Patent Application Publication
(10) Pub. No.: US 2007/0040275 A1
(43) Pub. Date: Feb. 22, 2007

(54) Semiconductor device including diffusion barrier and method for manufacturing the same

(76) Inventors: Han Choon Lee, Seoul (KR); In Cheol Baek, Daejeon (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/502,366

(22) Filed: Aug. 11, 2006

(30) Foreign Application Priority Data
Aug. 12, 2005 (KR) 10-2005-0074207

(51) Int. Cl. H01L 23/52; H01L 21/4763

(52) U.S. Cl. 257/751; 257/761; 257/774; 438/637; 438/653; 438/656; 438/680

(57) ABSTRACT

Provided are a semiconductor device including a diffusion barrier and a method for manufacturing the same. In the method, an interlayer insulating layer on a semiconductor substrate is formed. The interlayer insulating layer is selectively removed, so that a via hole is formed therein. A first diffusion barrier is formed on sidewalls and a bottom of the via hole using PEALD. A copper layer is formed above the first diffusion barrier, and CMP is performed on the copper layer until the interlayer insulating layer is exposed to form a copper line.

### RELATED APPLICATION

This application is based upon and claims the benefit of priority to Korean Application No. 10-2005-74207, filed on Aug. 12, 2005, the entire contents of which are incorporated herein by reference.

### BACKGROUND

1. Technical Field

The present invention relates to a semiconductor device and a method for manufacturing the same.

2. Description of the Related Art

In the related art, a copper line process for a semiconductor device uses a diffusion barrier formed by physical vapor deposition (PVD).

On the other hand, as a semiconductor device is miniaturized, a thickness of a diffusion barrier should be thin in a copper line process.

However, as a thickness of a diffusion barrier formed by the PVD decreases, the resistance of the diffusion barrier increases, adhesion between the diffusion barrier and copper becomes poor, and the diffusion barrier does not effectively prevent diffusion of copper. Also, it is difficult to obtain conformal step coverage.

### SUMMARY

Accordingly, the present invention is directed to a semiconductor device and a method for manufacturing the same that substantially obviate one or more problems due to limitations and disadvantages of the related art.

Embodiments consistent with the present invention provide a semiconductor device including a diffusion barrier having a thin thickness and low resistance, and a method for manufacturing the same. Embodiments consistent with the present invention further provide a semiconductor device including a diffusion barrier where adhesion between an oxide layer and copper is excellent, and a method for manufacturing the same.

Embodiments consistent with the present invention may also provide a semiconductor device including a diffusion barrier that can effectively prevent copper from diffusing, and a method for manufacturing the same.

Finally, embodiments consistent with the present invention may further provide a semiconductor device including a diffusion barrier having conformal step coverage with respect to patterns, and a method for manufacturing the same.

Additional advantages and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

Consistent with embodiments of the present invention there is provided a method for manufacturing a semiconductor device including a diffusion barrier, the method including: forming an interlayer insulating layer on a substrate; selectively removing portions of the interlayer insulating layer to form a via hole therein; forming a first diffusion barrier on sidewalls and a bottom of the via hole using a plasma enhanced atomic layer deposition (PEALD) process; forming a copper layer above the first diffusion barrier; and performing chemical mechanical polishing (CMP) on the copper layer until the remaining portions of the interlayer insulating layer are exposed to form a copper line.

Consistent with embodiments of the present invention a semiconductor device is provided including a diffusion barrier, the semiconductor device including: an interlayer insulating layer formed on a substrate, the interlayer insulating layer including a predetermined via hole; a first diffusion barrier layer formed on sidewalls and a bottom of the via hole using PEALD; and a copper line formed above the first diffusion barrier.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1 to 5 are cross-sectional views explaining a process of forming a diffusion barrier of a copper line consistent with an embodiment of the present invention;

FIG. 6 shows Auger electron spectroscopy (AES) chemical composition analysis results obtained of a TaN layer deposited using plasma enhanced atomic layer deposition (PEALD) wherein the following are used as the plasma treatment gas: (a) H₂ 300 sccm, N₂ 100 sccm (b) H₂ 300 sccm, N₂ 50 sccm (c) H₂ 300 sccm;

FIG. 7 is a graph showing the variation of resistivity of a PEALD TaN layer deposited at a temperature of 300° C. versus a plasma gas;

FIG. 8 is a graph showing the variation of resistivity of a PEALD TaN layer treated with a hydrogen gas versus deposition temperature;

FIG. 9 shows graphs showing AES analysis results of a PEALD TaN layer deposited using a hydrogen gas for a plasma treatment gas at deposition temperatures of (a) 200° C., (b) 250° C. (c) 300° C., and (d) 350° C.

FIG. 10 illustrates tape test results for (a) a PEALD TaN layer and (b) a PEALD TaN layer (50 Å)/PVD tantalum layer (75 Å);

FIG. 11 shows SEM images of the surface of a seed copper obtained by heat-treating a diffusion barrier of (a) ALD TaN (25 Å):reflection ratio=95%, (b) ALD TaN/PVD Ta (25/75 Å): reflection ratio=98%, (c) ALD TaN 50(Å): reflection ratio=96%, and (d) ALD TaN/PVD Ta 50/75(Å): reflection ratio=99%, for one hour at 370° C.

FIG. 12 shows graphs showing AES analysis results of a diffusion barrier of (a) PVD TaN/Ta (150/150 Å), (b) ALD TaN (25 Å), (c) ALD TaN (50 Å), (d) ALD TaN/PVD Ta (25/75 Å), (e) ALD TaN/PVD Ta (75/50 Å);

FIG. 13 is a cross-sectional SEM image illustrating a PEALD TaN layer deposited for 200 cycles in a via hole having a width of 0.18 μm;

FIG. 14 shows graphs showing via contact resistance of (a) a PEALD TaN layer and (b) a PEALD TaN using a punch-through process, respectively; and

FIG. 15 shows cross-sectional SEM images showing (a) a PEALD TaN layer and (b) a PEALD TaN layer using a punch-through process, respectively.

### DETAILED DESCRIPTION

Reference will now be made in detail to the embodiments consistent with the present invention, examples of which are illustrated in the accompanying drawings.

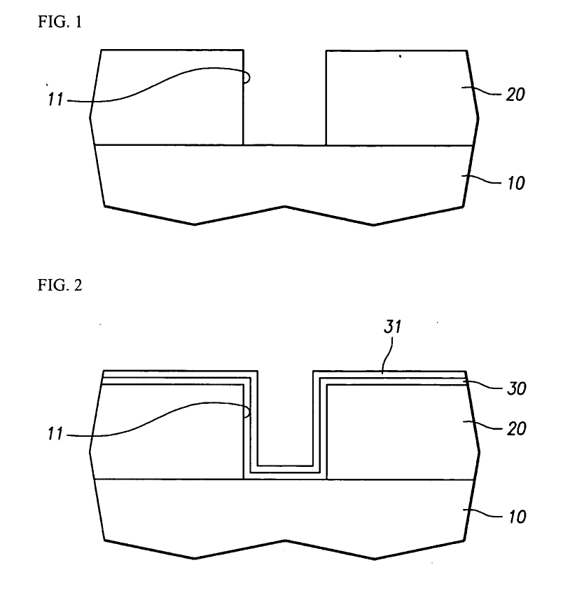

FIGS. 1 to 5 are cross-sectional views explaining a process of forming a diffusion barrier of a copper line consistent with an embodiment of the present invention.

Referring to FIG. 1, an interlayer insulating layer 20 is formed on a substrate 10. A via hole 11 is formed by performing a general photolithography process on the interlayer insulating layer 20.

For example, via hole 11 can be formed to have an aspect ratio of about 6:1, a width of about 0.18 μm, and a depth of about 1.08 μm.

Referring to FIG. 2, a first diffusion barrier 30 can be formed along sidewalls and a bottom of the via hole 11. In an embodiment consistent with the present invention, first diffusion barrier 30 may be a TaN layer.

Also, consistent with an embodiment of the present invention, a second diffusion barrier 31 may be formed on the first diffusion barrier 30. The second diffusion barrier 31 may be a Ta layer.

The TaN layer (first diffusion barrier) 30 may be deposited using a PEALD process in which plasma treatment is performed in order to remove impurities contained inside a thin film and improve compactness of a thin film.

A precursor of the TaN layer 30 may include a halogen compound such as TaCl5, and metal-organic materials such as tertbutylimido trisdiethylamide tantalum (TBTDET), pentakis diethylamide tantalum (PDEAT), pentakis dimethylamide tantalum (PDMAT), or pentakis ethylmethylamino tantalum (PEMAT).

For example, when PEMAT is used for the precursor of the TaN layer 30, TaN layer 30 can be made to have low resistivity by controlling impurity (oxygen and carbon) content inside a layer at a deposition temperature of about 300° C.

Also, plasma is generated by mounting a power supply unit having a frequency of about 13.56 MHz in a shower-head shaped reaction gas inlet and a reactor and supplying a power of about 300 W.

Also, a hydrogen gas may be used as a plasma gas to reduce the resistivity and to improve compactness of a thin film.

One cycle of the PEALD process includes a six steps: (1) purging a chamber and a gas line, (2) injecting a PEMAT precursor and depositing the precursor on a substrate, (3) purging the chamber and the gas line, (4) opening a plasma gas valve, (5) applying plasma power and performing plasma treatment, and (6) cutting off the plasma power and the plasma gas.

Here, the TaN layer 30 having excellent uniformity and no impurities may be formed by performing about 200-400 cycles of the PEALD process on the PEMAT precursor where in each cycle, a PEMAT precursor injection time is about 1-3 sec., a purge time is about 1-3 sec., and a plasma treatment time is about 10-15 sec.

For example, the TaN layer 30 may be formed by performing about 300 cycles of the PEALD process where in each cycle, a purge time is about 2 sec., a PEMAT precursor injection time is about 2 sec., and a plasma treatment time is about 12 sec.

Next, the Ta layer 31 is deposited on the TaN layer 30 using PVD, so that a diffusion barrier layer formed of a double layer of PEALD TaN layer 30/PVD Ta layer 31 is formed.

Next, the substrate 10 may be subjected to heat treatment. The heat treatment may be performed at a temperature of about 370° C. for about one hour. Here, the heat treatment is performed to improve adhesion between a seed cupper layer 40 and the diffusion barrier formed of the TaN layer 30/Ta layer 31.

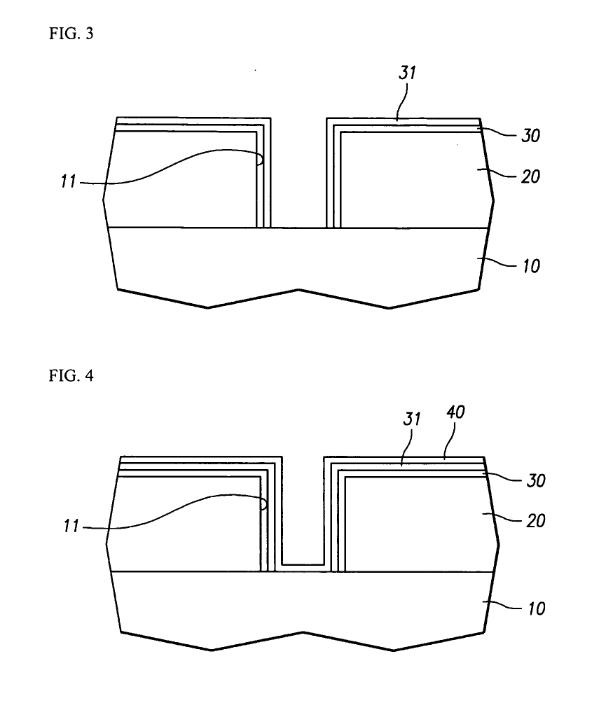

Next, referring to FIG. 3, a punch-through process for selectively etching a portion of the TaN layer 30/Ta layer 31 that is located on a bottom of the via hole 11, is performed. The punch-through process is intended for removing the portion of the TaN layer 30/Ta layer 31 that is located on the bottom of the via hole 11 to allow a copper line to directly contact the substrate 10. By doing so, chain resistance having a direct influence on an operation characteristic of a semiconductor device may be reduced.

Referring to FIG. 4, a seed layer 40 may be formed on the diffusion barrier of the TaN layer 30/Ta layer 31. The seed layer 40 may be formed of copper, for example.

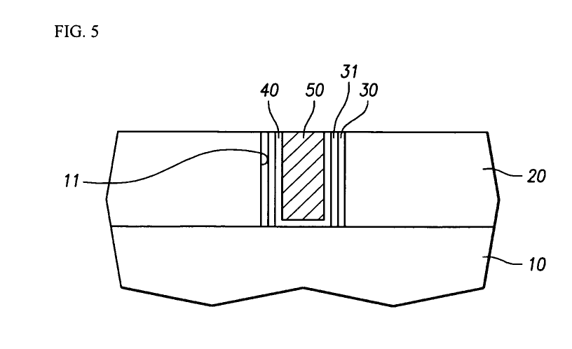

Referring to FIG. 5, a copper layer sufficiently filling the via hole 11 is formed on the copper seed layer 40 using electroplating. The copper layer is polished using a CMP process until the interlayer insulating layer 20 is exposed, so that a copper line (metal line) 50 is formed.

Next, resistivity and adhesive force of a diffusion barrier formed of a TaN/Ta layer consistent with an embodiment of the present invention, step coverage, and a chain resistance characteristic of a diffusion barrier are analyzed.

First, to analyze a characteristic of resistivity determining an operation speed of a device, a resistivity characteristic with respect to a plasma gas and deposition temperature which have the greatest influence on resistivity during a process are analyzed.

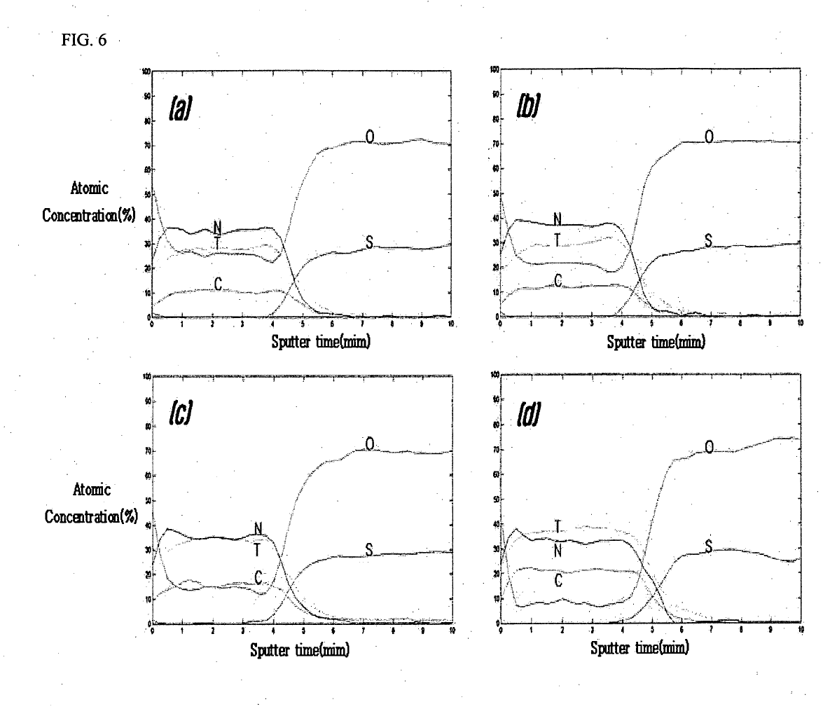

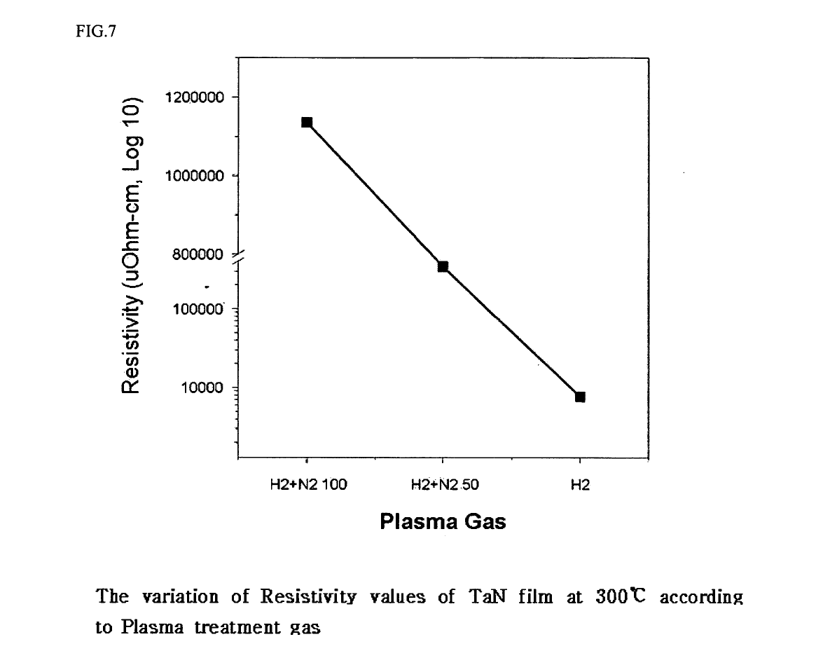

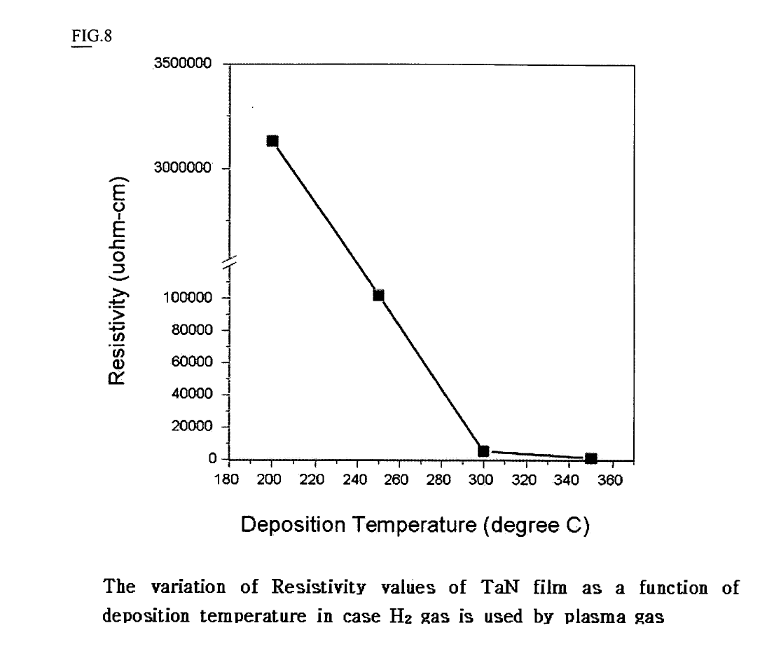

Regarding a resistivity characteristic with respect to a plasma gas, auger electron spectroscopy (AES) analysis results for a kind of a gas used for plasma treatment are shown in FIG. 6.

Here a TaN layer is deposited by performing 300 cycles of a PEALD process at a temperature of about 300° C., a deposition speed of 0.8 Å/cycle.

Referring to FIG. 6, when a mixture of H₂ and N₂ is used as a plasma gas, a formed TaN layer may have an impurity (oxygen and carbon) content of 10% or less, and has a high content of nitrogen. This occurs because C is replaced by N during the plasma treatment, so that the nitrogen content within the TaN layer increases and carbon is removed in the form of a CH-based compound by bonding with hydrogen, and oxygen is removed in the form of H₂O.

When H₂ is used as a plasma gas, a TaN layer formed by PEALD may have an impurity (oxygen and carbon) content of about 15%, and nitrogen content of about 40%. Therefore, plasma treatment performed using a mixture of H₂ and N₂ has an effect of excellent impurity removal.

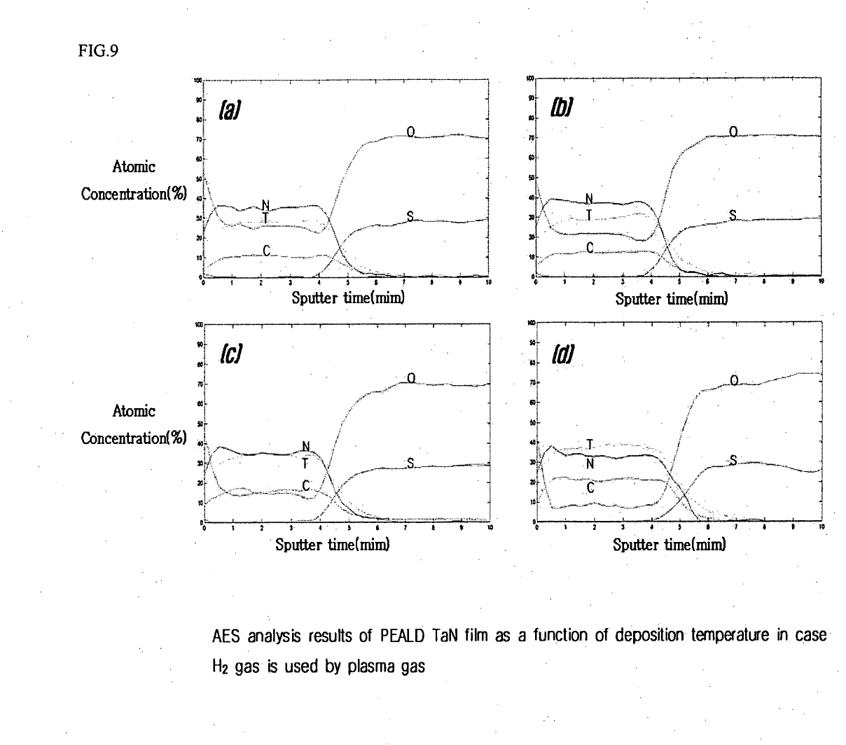

On the other hand, referring to FIG. 7, when only H₂ is used as a plasma gas, there is an advantage of small resistivity of about 7000 mΩ·cm. This is because the phase of a TaN layer changes depending on the nitrogen content inside the TaN layer.

That is, when a mixture of H₂ and N₂ is used as a plasma gas, C is replaced by N, so that a face-centered cubic (fcc) TaN layer is formed. The fcc-TaN layer has a crystalline structure and has a high resistivity of 10,000 mΩ·cm or more. Therefore, it is advantageous to use only hydrogen gas to achieve low resistivity.

Next, regarding a resistivity characteristic with respect to deposition temperature, the change of resistivity change of PEALD TaN layer with deposition temperature is shown in FIG. 8.

Here, the PEALD TaN layer is formed with H₂ used as the plasma gas, and by performing about 400 cycles of the PEALD process using PEMAT, and a has thickness of about 320 Å.

Referring to FIG. 8, the resistivity of the TaN layer drastically changes depending on deposition temperature and has a low resistivity of 960 mΩ·cm at the temperature of 300° C.

FIG. 9 shows AES analysis results of when H₂ is used as a plasma gas.

When H₂ is used for a plasma gas, nitrogen content within the TaN layer has a relatively constant nitrogen content of about 30-40% therein regardless of deposition temperature. On the other hand, as the deposition temperature increases, Ta and C components within the layer gradually increases, and oxygen content reduces.

Referring to FIGS. 8 and 9, the resistivity of a TaN layer decreases as a ratio of N to Ta decreases. It is advantageous to raise temperature to obtain a PEALD TaN layer having low resistivity. However, at an excessively high temperature exceeding 350° C., a CVD characteristic appears and thus it is difficult to control a thickness and impurities within the layer increases. Also, at an excessively low temperature of 250° C. or less, resistivity drastically increases. Therefore, an appropriate process temperature for forming a TaN layer is in a range of about 250-350° C.

Next, one of the characteristics of a diffusion barrier, an adhesion characteristic between copper and the diffusion barrier is analyzed. The analysis has been made for two cases. In one case, a single layer consisting of a PEALD TaN layer is used for the diffusion layer. In the other case, a double layer consisting of a PEALD TaN layer and a PVD Ta layer formed thereon is used for the diffusion layer, and adhesion between a seed copper layer and the double layer is analyzed.

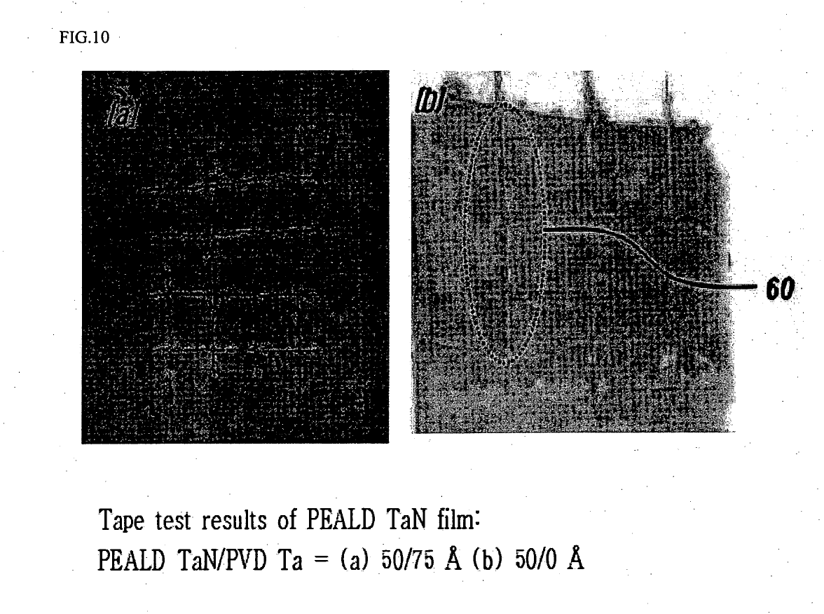

FIG. 10 shows graphs for the case where the single layer consisting of the PEALD TaN layer is used for the diffusion layer, and the case where the double layer consisting of the PEALD TaN layer and the PVD Ta layer formed thereon is used for the diffusion layer, and a seed layer is deposited, and a tape test is performed. In a case (a), there is no peeling of the surface of a thin layer. On the other hand, in a case (b) where only the PEALD TaN layer is used for the diffusion layer, peeling 60 of the surface of a thin layer occurs.

That is, adhesion of a single PEALD TaN used for a diffusion barrier consistent with an embodiment of the present invention is better than that of a single PVD TaN layer used for a diffusion barrier according to a related art.

Also, a double layer consisting of a PEALD TaN layer and a PVD Ta layer used for a diffusion barrier according to another embodiment of the present invention has even better adhesion.

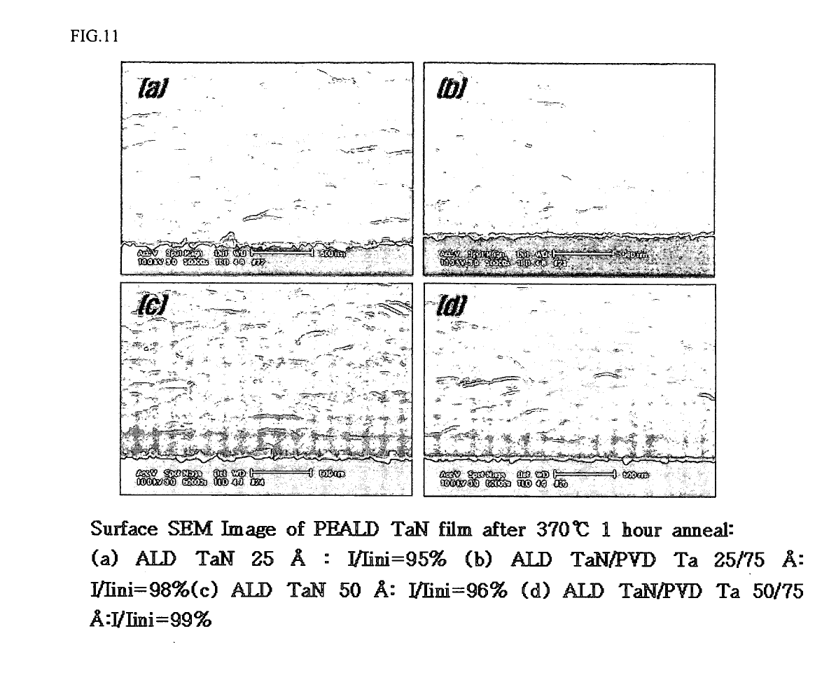

FIG. 11 shows SEM images of the surface of a copper seed layer formed on a diffusion barrier of (a) ALD TaN (25 Å), (b) ALD TaN/PVD Ta (25/75 Å), (c) ALD TaN (50 Å), and (d) ALD TaN/PVD Ta (50/75 Å), where the diffusion barrier is heat-treated for one hour at 370° C. The ratios of reflectivity (I) to initial reflectivity (Iᵢₙᵢ) for these examples are (a) I/Iᵢₙᵢ=95%, (b) I/Iᵢₙᵢ=98%, (c) I/Iᵢₙᵢ=96%, and (d) I/Iᵢₙᵢ=99%.

Under all conditions, agglomeration is not seen and reflectivity is more than 95% after heat treatment for one hour at 370° C. However, as is known from previous research, a PVD TaN layer has agglomeration and reflectivity of about 65% even after heat treatment.

Here, adhesion between an ALD TaN layer and a copper seed layer is better than that between a PVD TaN layer and a copper seed layer. However, referring to FIG. 10B, a double layer of a PEALD TaN/PVD Ta layer has even better adhesion than that of a single layer of a PEALD TaN layer.

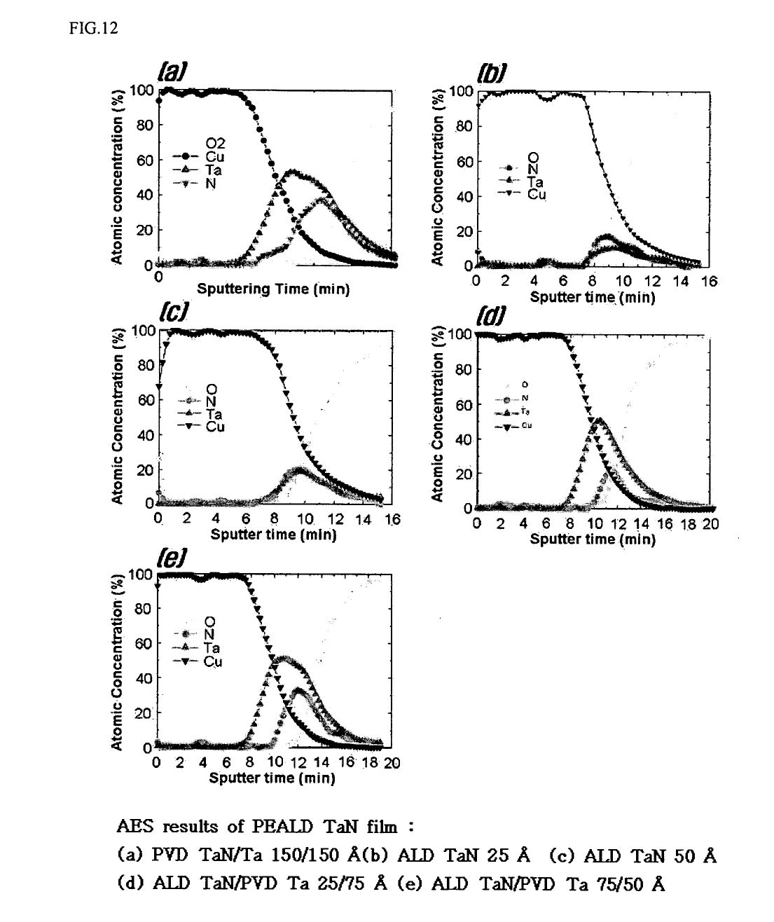

Next, FIG. 12 illustrates AES analysis results of components in order to examine characteristic of each diffusion barrier below. In both cases (b) and (c) where a single layer of an ALD TaN layer is used, copper penetrates into an oxide layer within the TaN layer and does not sufficiently serve as a diffusion barrier.

Both cases (d) and (e) where a double layer of an ALD TaN layer/PVD Ta layer is used have a thickness less than that of a case (a) where a double layer of a PVD TaN layer/Ta layer is used, but in the cases (d) and (e), copper does not diffuse into an oxide layer as in the case (a).

Therefore, even in an aspect of a diffusion barrier characteristic of a PEALD TaN layer, it is more advantageous to use a double layer of TaN layer/Ta layer rather than a single layer.

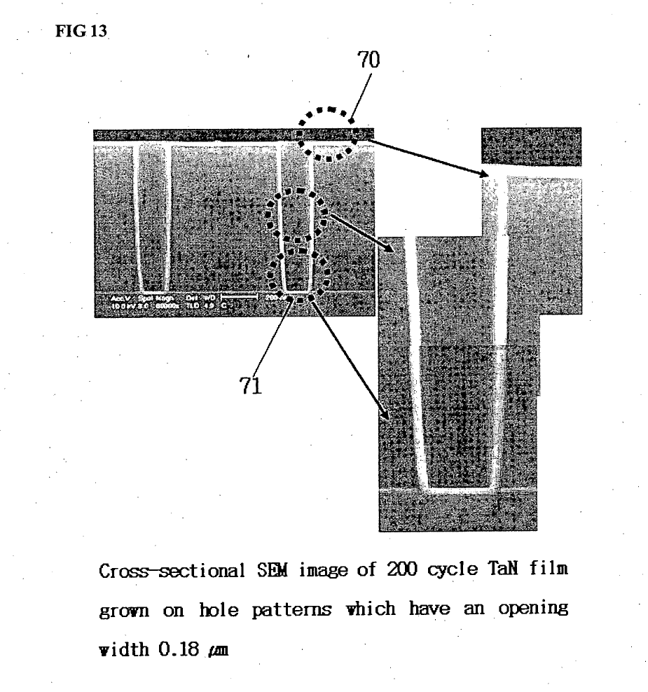

Next, FIG. 13 illustrates an SEM analysis results of step coverage of a PEALD Ta layer deposited with 200 cycles under conditions of a single pattern with via holes having a width of 0.18 μm and an aspect ratio of about 6:1, a deposition temperature of 300° C., and H₂ used as a plasma gas. Referring to FIG. 13, side coverage 70 of a TaN layer is about 95%, and bottom coverage 71 is about 80%, which are considered to be excellent step coverage.

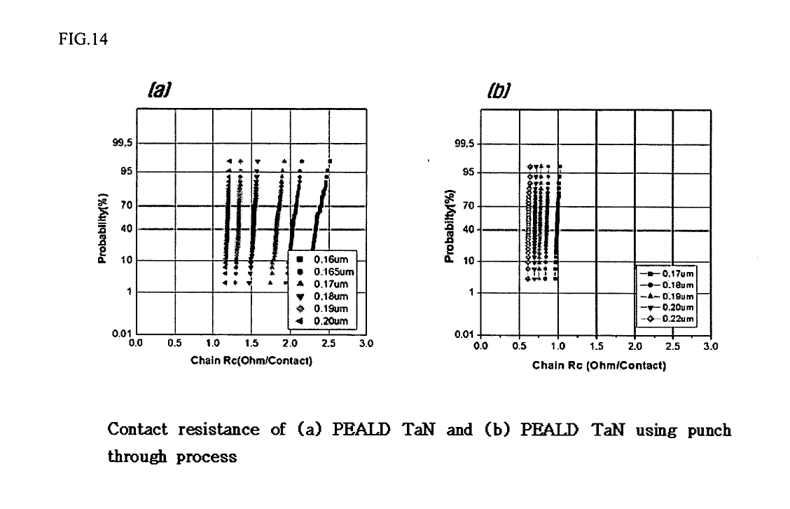

Next, regarding via chain resistance having a direct influence on an operation characteristic of a semiconductor device, FIG. 14 illustrates results of measurements of via chain resistance obtained by depositing copper through electroplating using a PEALD TaN layer as a diffusion barrier for a pattern used for an actual semiconductor device, and performing CMP. (a) shows chain resistance measured when a general process is performed, and (b) shows chain resistance measured when a punch-through process is added. The punch-through process reduces chain resistance by selectively etching TaN contained in a lower portion of a via hole using plasma to allow Cu to directly contact a substrate.

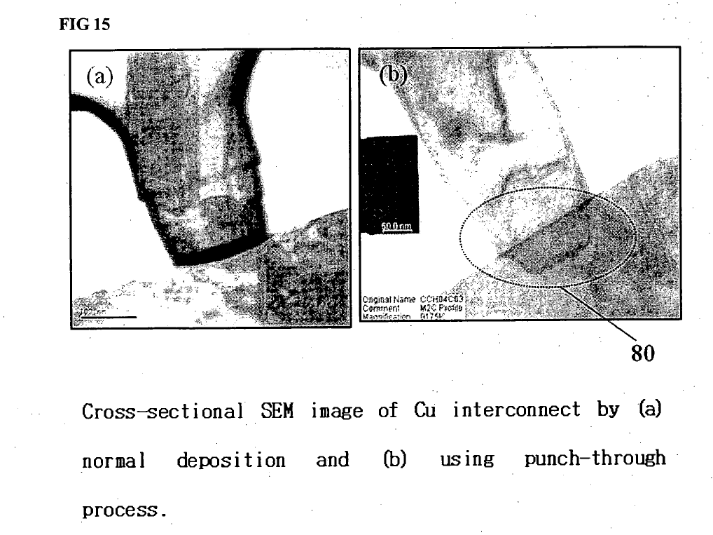

Accordingly, FIG. 15 is an SEM photo of a case (a) where a general process is performed, and a case (b) where a punch-through process is performed. In the case (b) where the punch-through process is performed, referring to FIG. 15, a copper layer located at a lower portion of the via hole is dug, so that contact 80 is formed. Referring to FIG. 14, a case (b) where a punch-through process is used has chain resistance of 0.6-1Ω/contact, which is reduction of 50% or more.

Because a PEALD TaN layer has a high resistivity, chain resistance using a PEALD TaN layer is also high. However, when a punch-through process is used, a sufficiently low chain resistance that can be used in an actual process can be obtained.

According to a semiconductor device including a diffusion barrier and a method for manufacturing the same, it is possible to manufacture a semiconductor device including a diffusion layer having excellent adhesion, diffusion barrier characteristics, excellent step coverage, a low resistivity, and a low chain resistance by forming a single layer of a PEALD TaN layer, or a double layer of a PEALD TaN/PVD Ta layer.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method for manufacturing a semiconductor device including a diffusion barrier, the method comprising:
forming an interlayer insulating layer on a semiconductor substrate;
selectively removing portions of the interlayer insulating layer to form a via hole therein;
forming a first diffusion barrier on sidewalls and a bottom of the via hole using a plasma enhanced atomic layer deposition (PEALD) process;
forming a copper layer above the first diffusion barrier; and
performing CMP (chemical mechanical polishing) on the copper layer until the remaining portions of the interlayer insulating layer are exposed to form a copper line.

2. The method according to claim 1, wherein the forming of the first diffusion barrier comprises forming a TaN layer using PEALD.

3. The method according to claim 2, wherein the forming of the TaN layer using PEALD comprises:
injecting and depositing a precursor for forming a TaN layer onto the substrate; and
performing plasma treatment on the substrate using H₂ for a plasma gas.

4. The method according to claim 3, wherein the performing of the plasma treatment comprises performing plasma treatment on the substrate using a mixture of H₂ and N₂ for a plasma gas.

5. The method according to claim 3, wherein the precursor for forming the TaN layer is a metal-organic precursor.

6. The method according to claim 3, wherein the precursor for forming the TaN layer is PEMAT (pentakis ethylmethylamino tantalum).

7. The method according to claim 3, wherein a deposition temperature during the performing of the plasma treatment is in a range of about 250-350° C.

8. The method according to claim 1, wherein the PEALD process comprises a plurality of cycles, and wherein one cycle of the PEALD comprises:
purging a chamber and a gas line;
injecting a PEMAT precursor and depositing the precursor on a substrate;
purging the chamber and the gas line;
opening a plasma gas valve;
applying plasma power and performing plasma treatment; and
cutting off the plasma power and the plasma gas.

9. The method according to claim 8, wherein the first diffusion barrier is deposited by performing about 200-400 cycles of the PEALD process, where a time for purging is about 1-3 sec., the time of injecting a precursor into the first diffusion barrier is about 1-3 sec., and the time of the plasma treatment is about 10-15 sec.

10. The method according to claim 1, further comprising forming a second diffusion barrier on the first diffusion barrier using a PVD (physical vapor deposition).

11. The method according to claim 10, wherein the forming of the second diffusion barrier comprises forming a Ta layer using PVD.

12. The method according to claim 1, further comprising forming a copper seed layer for plating copper above the diffusion barrier.

13. The method according to claim 1, further comprising, before the forming of the copper layer, selectively removing the first diffusion barrier layer formed on the bottom of the via hole to expose a portion of the semiconductor substrate that is located under the via hole.

14. The method according to claim 1, further comprising annealing the semiconductor substrate having the copper layer.

15. A semiconductor device including a diffusion barrier, the semiconductor device comprising:
an interlayer insulating layer formed on a substrate, the interlayer insulating layer including a predetermined via hole ;
a first diffusion barrier layer formed on sidewalls and a bottom of the via hole using a plasma enhanced atomic layer deposition (PEALD) process; and
a copper line formed above the first diffusion barrier.

16. The semiconductor device according to claim 15, wherein the first diffusion barrier is a TaN layer formed using PEALD.

17. The semiconductor device according to claim 16, further comprising a second diffusion barrier formed on the TaN layer using PVD.

18. The semiconductor device according to claim 17, wherein the second diffusion barrier is a Ta layer formed using PVD.

19. The semiconductor device according to claim 15, wherein the copper forms a contact with a portion of the substrate that is located under the via hole through a punch-through process comprising selectively removing a portion of the first diffusion barrier that is formed on the bottom of the via hole.

20. The semiconductor device according to claim 15, wherein the via hole has an aspect ratio of about 6:1 or greater.
